(19) United States
(12) Patent Application Publication
(10) Pub. No.: US 2022/0134505 A1
(43) Pub. Date: May 5, 2022

(54) HORIZONTAL BUFFING MODULE

(71) Applicant: Applied Materials, Inc., Santa Clara, CA (US)

(72) Inventors: Edward GOLUBOVSKY, San Jose, CA (US); Clinton SAKATA, San Jose, CA (US); Jagan RANGARAJAN, San Jose, CA (US); Ekaterina A. MIKHAYLICHENKO, San Jose, CA (US); Steven M. ZUNIGA, Soquel, CA (US)

(21) Appl. No.: 17/510,111

(22) Filed: Oct. 25, 2021

Related U.S. Application Data
(60) Provisional application No. 63/110,067, filed on Nov. 5, 2020.

(51) Int. Cl. B24B 37/04; B24B 37/30; B24B 37/10; B24B 37/34

(52) U.S. Cl. CPC B24B 37/042; B24B 37/345; B24B 37/105; B24B 37/30

(57) ABSTRACT

A horizontal pre-clean (HPC) module for a chemical mechanical polishing (CMP) processing system is disclosed. The HPC module includes a chamber having a basin and a lid which collectively define a processing area. The module includes a rotatable vacuum table disposed in the processing area, the rotatable vacuum table including an array of channels defined in a supporting surface thereof. The module includes a pad conditioning station disposed proximate to the rotatable vacuum table. The module includes a pad carrier positioning arm coupled to a pad carrier assembly. The module includes an actuator coupled to the pad carrier positioning arm and configured to position the pad carrier assembly between a first position over the rotatable vacuum table and a second position over the pad conditioning station.

### CROSS-REFERENCE TO RELATED CASES

This application claims the benefit of U.S. Provisional Patent Application No. 63/110,067, filed Nov. 5, 2020, which is incorporated by reference herein in its entirety.

### BACKGROUND

### Field

Embodiments described herein generally relate to equipment used in the manufacturing of electronic devices, and more particularly, to a horizontal buffing module which may be used to clean the surface of a substrate in a semiconductor device manufacturing process.

### Description of the Related Art

Chemical mechanical polishing (CMP) is commonly used in the manufacturing of high-density integrated circuits to planarize or polish a layer of material deposited on a substrate. In a typical CMP process, a substrate is retained in a carrier head that presses the backside of the substrate towards a rotating polishing pad in the presence of a polishing fluid. Material is removed across the material layer surface of the substrate in contact with the polishing pad through a combination of chemical and mechanical activity which is provided by the polishing fluid and a relative motion of the substrate and the polishing pad. Typically, after one or more CMP processes are complete a polished substrate is further processed to one or more post-CMP substrate processing operations. For example, the polished substrate may be further processed using one or a combination of cleaning, inspection, and measurement operations. Once the post-CMP operations are complete, a substrate can be sent out of a CMP processing area to the next device manufacturing process, such as a lithography, etch, or deposition process.

To conserve valuable manufacturing floor space and reduce labor costs, a CMP system commonly includes a first portion, e.g., a front portion, comprising one or a combination of post-CMP cleaning, inspection, and/or pre or post-CMP metrology stations and a second portion, e.g., a back portion which is integrated with the first portion to form a single polishing system. The second portion may comprise a plurality of polishing stations.

The first portion may comprise one or a plurality of vertical buffing modules for post-CMP cleaning of a substrate. Each vertical buffing module has a rotating chuck assembly for holding a substrate and a rotating buffing pad for cleaning a substrate surface. Unfortunately, the orientation of the vertical buffing module limits an outer diameter of the buffing pad such that only a limited area of a substrate can be cleaned at a given time. Thus, the substrate processing throughput is undesirably reduced according to the longer buffing times associated with the limited cleaning area of the buffing pad.

Further, because the vertical buffing module holds a substrate in a vertical orientation, the vertical orientation of the substrate loaded in the vertical buffing module requires a large overhead clearance for insertion and removal of the substrate. As a result, an overall size and/or footprint of the CMP system is undesirably increased according to the larger overhead clearance requirements associated with the vertical orientation of the buffing module. Thus, the throughput density (substrates processed per unit time per unit area of manufacturing floor space) of a CMP system is undesirably limited by the system's buffing module configuration.

Accordingly, what is needed in the art are apparatus and methods for solving the problems described above.

### SUMMARY

Embodiments described herein generally relate to equipment used in the manufacturing of electronic devices, and more particularly, to a horizontal buffing module which may be used to clean the surface of a substrate in a semiconductor device manufacturing process.

In one embodiment, a substrate processing module includes a chamber having a basin and a lid which collectively define a processing area. The module includes a rotatable vacuum table disposed in the processing area, the rotatable vacuum table including a plurality of annular channels defined in a substrate receiving surface thereof. The module includes a pad conditioning station disposed proximate to the rotatable vacuum table. The module includes a pad carrier positioning arm having a first end and a second end distal from the first end, where the first end is coupled to a pad carrier assembly and the second end is coupled to an actuator configured to swing the pad carrier assembly between a first position over the rotatable vacuum table and a second position over the pad conditioning station.

In another embodiment, a method of processing a substrate includes positioning a substrate on a vacuum table of a substrate processing module. The vacuum table includes a plurality of annular channels defined in a substrate receiving surface thereof. The substrate receiving surface of the vacuum table is substantially orthogonal to the direction of gravity. A grip area provided by the plurality of annular channels is between about 5% and about 30% of a surface area of the substrate positioned thereon. The grip area includes the effective area occupied by the plurality of channels in the substrate receiving surface of the vacuum table. The method includes urging a buffing pad against a surface of the substrate while rotating the vacuum table there beneath. The buffing pad has a diameter of about 67 mm or more and a pressure applied between the buffing pad and the surface of the substrate is about 3 psi or more.

In yet another embodiment, a modular substrate processing system includes a substrate processing module. The module includes a chamber including a basin and a lid. The lid includes a plurality of side panels which, with the basin, collectively define a processing area. The module includes a rotatable vacuum table disposed in the processing area. The module includes a first substrate handler access door disposed in a first side panel of the plurality of side panels. The substrate handler access door is used for positioning a substrate on the rotatable vacuum table with a first substrate handler. The module includes a second substrate handler access door disposed in a second side panel of the plurality of side panels. The second substrate handler access door is used for removing the substrate from the rotatable vacuum table with a second substrate handler. The module includes a pad conditioning station disposed proximate to the rotatable vacuum table. The module includes a pad carrier positioning arm having a first end and a second end distal from the first end. The first end is coupled to a pad carrier assembly and the second end is coupled to an actuator configured to swing the pad carrier assembly between a first position over the rotatable vacuum table and a second position over the pad conditioning station.

In another embodiment, a substrate processing module includes a rotatable vacuum table disposed in a processing area of the substrate processing module, the rotatable vacuum table including a supporting surface that includes an array of channels. The module includes a pad conditioning station disposed proximate to the rotatable vacuum table. The module includes a pad carrier positioning arm coupled to a pad carrier assembly. The module includes an actuator coupled to the pad carrier positioning arm and configured to position the pad carrier assembly over a first position disposed over the supporting surface of the rotatable vacuum table and over a second position disposed over the pad conditioning station.

In another embodiment, a method of processing a substrate includes positioning a substrate on a vacuum table of a substrate processing module. The vacuum table includes an array of channels defined in a supporting surface thereof. The supporting surface of the vacuum table is substantially orthogonal to a direction of gravity. A grip area provided by the array of channels is between about 5% and about 30% of a surface area of the substrate positioned thereon. The grip area includes an effective area occupied by the array of channels in the supporting surface of the vacuum table. The method includes urging a buffing pad against a surface of the substrate while rotating the vacuum table there beneath. The buffing pad has a diameter of about 67 mm or more and a pressure applied between the buffing pad and the surface of the substrate is about 3 psi or more.

In another embodiment, a modular substrate processing system includes a substrate processing module. The module includes a chamber including a basin and a lid. The lid includes a plurality of side panels which, with the basin, collectively define a processing area. The module includes a rotatable vacuum table disposed in the processing area. The module includes a first substrate handler access door disposed in a first side panel of the plurality of side panels. The substrate handler access door is used for positioning a substrate on the rotatable vacuum table with a first substrate handler. The module includes a second substrate handler access door disposed in a second side panel of the plurality of side panels. The second substrate handler access door is used for removing the substrate from the rotatable vacuum table with a second substrate handler. The module includes a pad conditioning station disposed proximate to the rotatable vacuum table. The module includes a pad carrier positioning arm coupled to a pad carrier assembly. The module includes an actuator coupled to the pad carrier positioning arm and configured to position the pad carrier assembly over a first position disposed over the supporting surface of the rotatable vacuum table and over a second position disposed over the pad conditioning station.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1A is a schematic plan view of an exemplary chemical mechanical polishing (CMP) processing system, which uses a horizontal pre-clean (HPC) module described herein, according to one or more embodiments.

FIG. 1B is a top isometric view of an exemplary CMP processing system, which may correspond to the schematic view shown in FIG. 1A, according to one or more embodiments.

FIG. 1C is a top elevation view of the CMP processing system of FIG. 1B, which may correspond to the schematic view shown in FIG. 1A, according to one or more embodiments.

FIG. 2A is a top isometric view of one side of an exemplary HPC module which may be used in the CMP processing system described herein.

FIG. 2B is another top isometric view of the side of the HPC module of FIG. 2A.

FIG. 2C is a top isometric view of another side of the HPC module of FIG. 2A.

FIG. 3A is a side sectional view taken along section line 3A-3A of FIG. 2C.

FIGS. 3B-3C are bottom and top isometric views, respectively, of an exemplary rotatable vacuum table which may be used in the HPC module of FIG. 3A.

FIG. 3D is a plan view of an exemplary carrier film which may be used with the rotatable vacuum table of FIGS. 3B-3C.

FIG. 3E is an enlarged plan view of a portion of FIG. 3D.

FIG. 4A is a plan view of the HPC module of FIG. 3A.

FIG. 4B is a side sectional view of an exemplary pad conditioning station which may be used in the HPC module of FIG. 3A.

FIG. 4C is a side sectional view of an exemplary pad carrier positioning arm which may be used in the HPC module of FIG. 3A.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments described herein generally relate to equipment used in the manufacturing of electronic devices, and more particularly, to a horizontal buffing module which may be used to clean the surface of a substrate in a semiconductor device manufacturing process.

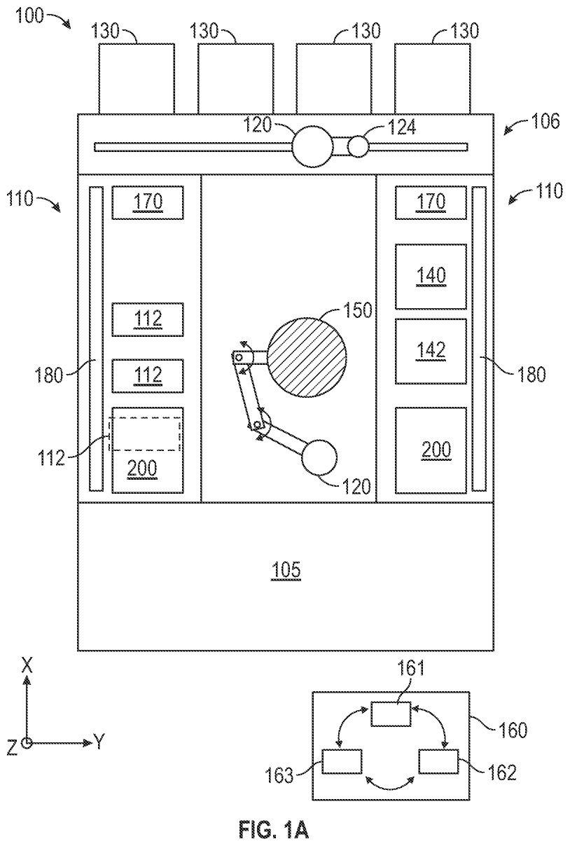

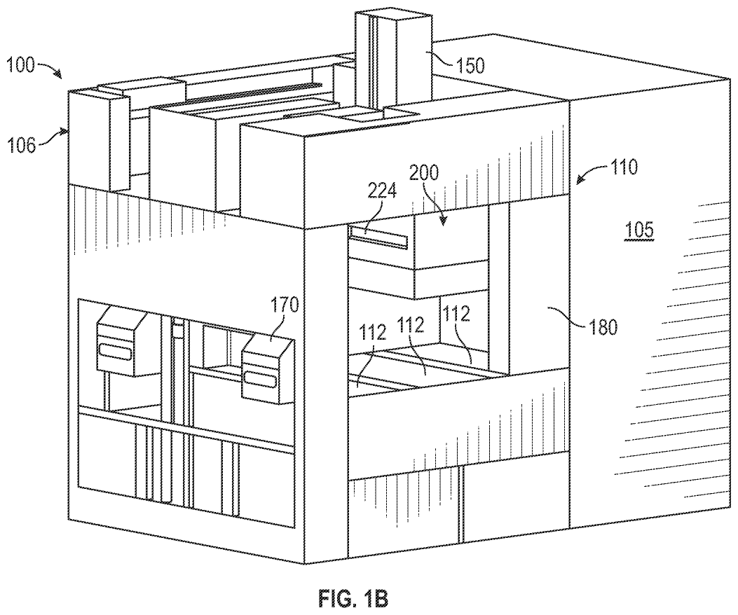

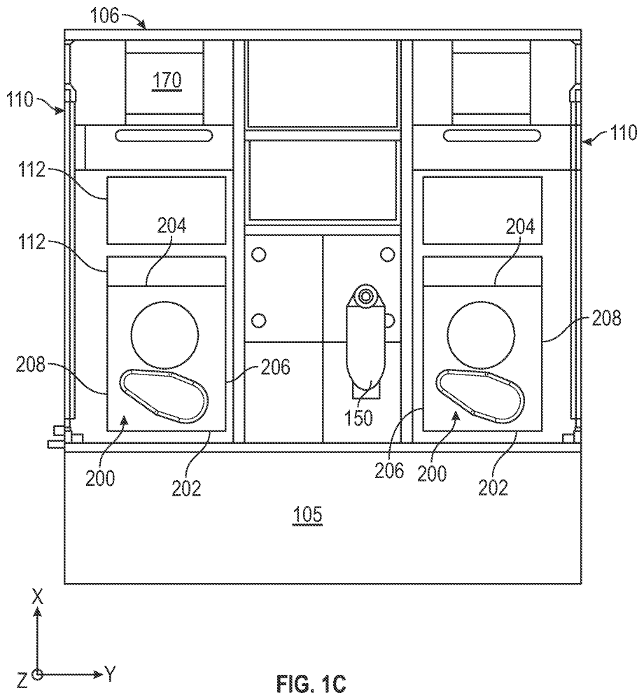

FIG. 1A is a schematic plan view of an exemplary chemical mechanical polishing (CMP) processing system 100, which uses a horizontal pre-clean (HPC) module described herein, according to one or more embodiments. FIG. 1B is a top isometric view of an exemplary CMP processing system 100 which may correspond to the schematic view shown in FIG. 1A, according to one or more embodiments. FIG. 1C is a top elevation view of the CMP processing system 100 of FIG. 1B which may correspond to the schematic view shown in FIG. 1A, according to one or more embodiments. In FIGS. 1B and 1C, certain parts of the housing and certain other internal and external components are omitted to more clearly show the HPC module within the CMP processing system 100. Here, the processing system 100 includes a first portion 105 and a second portion 106 coupled to the first portion 105 and integrated therewith. The first portion 105 is a substrate polishing portion featuring a plurality of polishing stations (not shown).

The second portion 106 includes one or more post-CMP cleaning systems 110, a plurality of system loading stations 130, one or more substrate handlers, e.g., a first robot 124 and a second robot 150, one or more metrology stations 140, one or more location specific polishing (LSP) modules 142, one or more HPC modules 200, and one or more drying units 170. The HPC module 200 is configured to process a substrate 120 disposed in a substantially horizontal orientation (i.e., in the x-y plane). In some embodiments, the second portion 106 optionally includes one or more vertical cleaning modules 112 configured to process substrates 120 disposed in substantially vertical orientations (i.e., in the z-y plane).

Each LSP module 142 is typically configured to polish only a portion of a substrate surface using a polishing member (not shown) that has a surface area that is less than the surface area of a to-be polished substrate 120. LSP modules 142 are often used after the substrate 120 has been polished with a polishing module to touch up, e.g., remove additional material, from a relatively small portion of the substrate.

The metrology station 140 is used to measure the thickness of a material layer disposed on the substrate 120 before and/or after polishing, to inspect the substrate 120 after polishing to determine if a material layer has been cleared from the field surface thereof, and/or to inspect the substrate surface for defects before and/or after polishing. In those embodiments, the substrate 120 may be returned to the polishing pad for further polishing and/or directed to a different substrate processing module or station, such as a polishing module within the first portion 105 or to an LSP module 142 based on the measurement or surface inspection results obtained using the metrology station 140. As shown in FIG. 1A, a metrology station 140 and an LSP module 142 are located in a region of the second portion 106 that is above (in the Z-direction) portions of one of the cleaning systems 110.

The first robot 124 is positioned to transfer substrates 120 to and from the plurality of system loading stations 130, e.g., between the plurality of system loading stations 130 and the second robot 150 and/or between the cleaning system 110 and the plurality of system loading stations 130. In some embodiments, the first robot 124 is positioned to transfer the substrate 120 between any of the system loading stations 130 and a processing system positioned proximate thereto. For example, in some embodiments, the first robot 124 may be used to transfer the substrate 120 between one of the system loading stations 130 and the metrology station 140.

The second robot 150 is used to transfer the substrate 120 between the first portion 105 and the second portion 106. For example, here the second robot 150 is positioned to transfer a to-be-polished substrate 120 received from the first robot 124 to the first portion 105 for polishing therein. The second robot 150 is then used to transfer the polished substrate 120 from the first portion 105, e.g., from a transfer station (not shown) within the first portion 105, to one of the HPC modules 200 and/or between different stations and modules located within the second portion 106. Alternatively, the second robot 150 transfers the substrate 120 from the transfer station within the first portion 105 to one of the LSP modules 142 or the metrology station 140. The second robot 150 may also transfer the substrate 120 from either of the LSP modules 142 or the metrology station 140 to the first portion 105 for further polishing therein.

The CMP processing system 100 in FIG. 1A features two cleaning systems 110 disposed on either side of the second robot 150. In FIG. 1A at least some modules of one of the cleaning systems 110, e.g., one or more vertical cleaning modules 112, are located below (in the Z-direction) the metrology station 140 and the LSP module 142 and are thus not shown. The metrology station 140 and the LSP module 142 are not shown in FIG. 1C. In some other embodiments, the processing system 100 features only one cleaning system 110. Here, each of the cleaning systems 110 includes an HPC module 200, one or more wet cleaning modules 112, e.g., brush or spray boxes, a drying unit 170, and a substrate handler 180 for transferring substrates 120 therebetween. Here, each HPC module 200 is disposed within the second portion 106 in a location proximate to the first portion 105.

Typically, the HPC module 200 receives a polished substrate 120 from the second robot 150 through a first opening (not shown) formed in a side panel of the HPC module 200, e.g., though a door or a slit valve disposed in the side panel. The substrate 120 is received in a horizontal orientation by the HPC module 200 for positioning on a horizontally disposed substrate support surface therein. The HPC module 200 then performs a pre-clean process, such as a buffing process, on the substrate 120 before the substrate 120 is transferred therefrom using a substrate handler 180.

The substrate 120 is transferred from the HPC module 200 through a second opening, here a second substrate handler access door 224 (FIG. 1B), which is typically a horizontal slot disposed though a second side panel of the HPC module 200 closable with a door, e.g., a slit valve. Thus, the substrate 120 is still in a horizontal orientation as it is transferred from the pre-clean module 200. After the substrate 120 is transferred from the pre-clean module 200, the substrate handler 180 positions the substrate 120 to a vertical position for further processing in the vertical cleaning modules 112 of the cleaning system 110. For example, the substrate handler 180 may swing the substrate 120 to the vertical position.

In this example, the HPC module 200 has a first end 202 facing the first portion 105 of the processing system 100, a second end 204 facing opposite the first end 202, a first side 206 facing the second robot 150, and a second side facing opposite the first side 206. The first and second sides 206, 208 extend orthogonally between the first and second ends 202, 204.

The plurality of vertical cleaning modules 112 are located within the second portion 106. The one or more vertical cleaning modules 112 are any one or combination of contact and non-contact cleaning systems for removing polishing byproducts from the surfaces of a substrate, e.g., spray boxes and/or brush boxes.

The drying unit 170 is used to dry the substrate 120 after the substrate has been processed by the cleaning modules 112 and before the substrate 120 is transferred to a system loading station 130 by the first robot 124. Here, the drying unit 170 is a horizontal drying unit, such that the drying unit 170 is configured to receive a substrate 120 through an opening (not shown) while the substrate 120 is disposed in a horizontal orientation.

Herein, substrates 120 are moved between the HPC module 200 and the vertical cleaning modules 112, between individual ones of the cleaning modules 112, and between the cleaning modules 112 and the drying unit 170 using the substrate handler 180.

In embodiments herein, operation of the CMP processing system 100, including the substrate handler 180, is directed by a system controller 160. The system controller 160 includes a programmable central processing unit (CPU) 161 which is operable with a memory 162 (e.g., non-volatile memory) and support circuits 163. The support circuits 163 are conventionally coupled to the CPU 161 and comprise cache, clock circuits, input/output subsystems, power supplies, and the like, and combinations thereof coupled to the various components of the CMP processing system 100, to facilitate control thereof. The CPU 161 is one of any form of general purpose computer processor used in an industrial setting, such as a programmable logic controller (PLC), for controlling various components and sub-processors of the processing system. The memory 162, coupled to the CPU 161, is non-transitory and is typically one or more of readily available memories such as random access memory (RAM), read only memory (ROM), floppy disk drive, hard disk, or any other form of digital storage, local or remote.

Typically, the memory 162 is in the form of a non-transitory computer-readable storage media containing instructions (e.g., non-volatile memory), which when executed by the CPU 161, facilitates the operation of the CMP processing system 100. The instructions in the memory 162 are in the form of a program product such as a program that implements the methods of the present disclosure. The program code may conform to any one of a number of different programming languages. In one example, the disclosure may be implemented as a program product stored on computer-readable storage media for use with a computer system. The program(s) of the program product define functions of the embodiments (including the methods described herein).

Illustrative non-transitory computer-readable storage media include, but are not limited to: (i) non-writable storage media (e.g., read-only memory devices within a computer such as CD-ROM disks readable by a CD-ROM drive, flash memory, ROM chips or any type of solid-state non-volatile semiconductor memory devices, e.g., solid state drives (SSD) on which information may be permanently stored; and (ii) writable storage media (e.g., floppy disks within a diskette drive or hard-disk drive or any type of solid-state random-access semiconductor memory) on which alterable information is stored. Such computer-readable storage media, when carrying computer-readable instructions that direct the functions of the methods described herein, are embodiments of the present disclosure. In some embodiments, the methods set forth herein, or portions thereof, are performed by one or more application specific integrated circuits (ASICs), field-programmable gate arrays (FPGAs), or other types of hardware implementations. In some other embodiments, the substrate processing and/or handling methods set forth herein are performed by a combination of software routines, ASIC(s), FPGAs and, or, other types of hardware implementations. One or more system controllers 160 may be used with one or any combination of the various modular polishing systems described herein and/or with the individual polishing modules thereof.

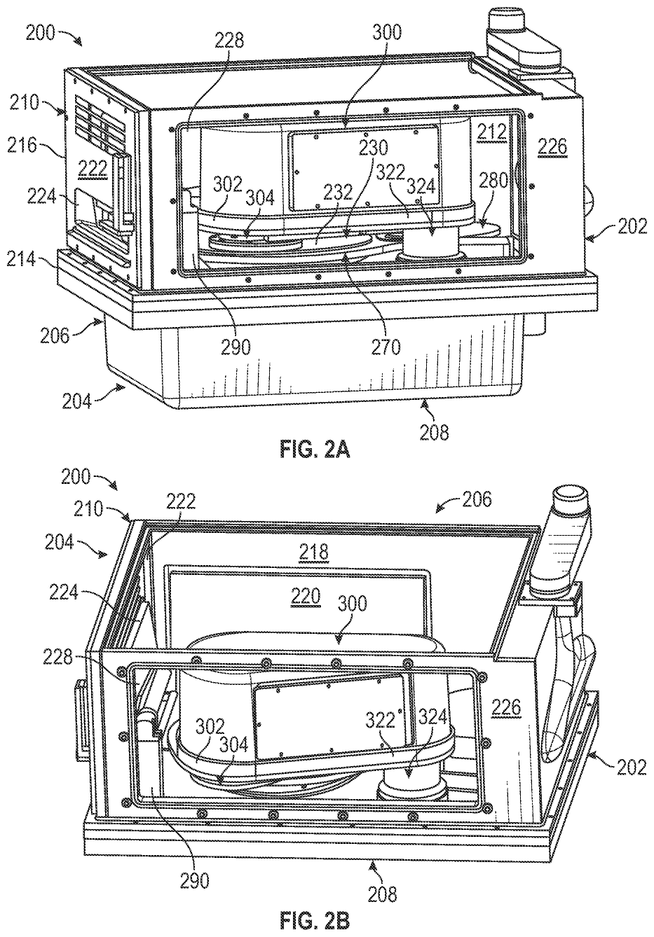

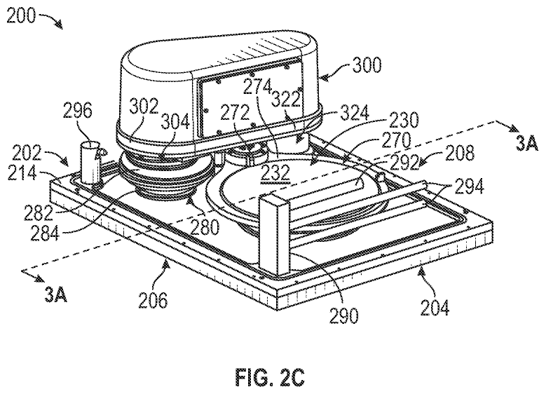

FIG. 2A is a top isometric view of a second side 208 of an exemplary HPC module 200 which may be used in the CMP processing system 100 described herein. In FIG. 2A, a service access panel is omitted to more clearly show the internal components of the HPC module 200. FIG. 2B is another top isometric view of the second side 208 of the HPC module 200 of FIG. 2A. In FIG. 2B, a top panel of a lid 216 is further omitted to more clearly show the internal components of the HPC module 200. FIG. 2C is a top isometric view of a first side 206 of the HPC module 200 of FIG. 2A. In FIG. 2C, the lid 216 is omitted to more clearly show the internal components of the HPC module 200.

Generally, the HPC module 200 includes a chamber 210, here a basin 214 and a lid 216, formed of a plurality of side panels which collectively define a processing area 212.

A first side panel 218 is formed on the first side 206 of the HPC module 200 facing the second robot 150. The first side panel 218 includes a first substrate handler access door 220 used for positioning a substrate 120 on a rotatable vacuum table 230 with the second robot 150. A second side panel 222 is formed on the second end 204 of the HPC module 200 facing away from the first portion 105. The second side panel 222 includes the second substrate handler access door 224 used for removing the substrate 120 from the rotatable vacuum table 230 with the substrate handler 180. A third side panel 226 is formed on the second side 208 of the HPC module 200. The third side panel 226 includes a service access panel opening 228. The symmetry of the first substrate handler access door 220 and the service access panel opening 228 formed on opposite side panels of the HPC module 200 beneficially provides a horizontal buffing module that can be installed on either side of the processing system 100 as illustrated in FIG. 1C.

The rotatable vacuum table 230 is disposed within the processing area 212 of the HPC module 200 and may be used for vacuum chucking a substrate 120. Also disposed within the processing area 212 may be an annular substrate lift mechanism 270 disposed radially outward of the rotatable vacuum table 230, a pad conditioning station 280 disposed proximate the rotatable vacuum table 230, and a pad carrier positioning arm 300 movable between a first position over the rotatable vacuum table 230 and a second position over the pad conditioning station 280. For example, the pad carrier positioning arm 300 may position the pad carrier assembly 304 over the first position disposed over the supporting surface of the rotatable vacuum table 230 and over the second position disposed over the pad conditioning station 280.

The rotatable vacuum table 230, the annular substrate lift mechanism 270, the pad conditioning station 280, and the pad carrier positioning arm 300 are each independently mounted to the basin 214. The HPC module 200 further includes a rinse manifold 290 mounted to the basin 214. A substrate center rinse bar 292 and one or more substrate spray bars 294 extend from a side of the rinse manifold 290. The substrate center rinse bar 292 is used for directing a rinse fluid, e.g., a cleaning fluid or water, towards a center area of the rotatable vacuum table 230. The substrate spray bars 294 are used for directing a spray towards one or more other areas of the rotatable vacuum table 230, e.g., a perimeter area or a side portion of the vacuum table 230. The rinse manifold 290 is positioned towards a corner of the basin 214, and the rinse bar 292 and spray bars 294 extend along the second end 204 of the HPC module 200 inside the second side panel 222. In some embodiments, the rinse manifold 290 is adjacent to the second side 208 (FIGS. 2A-2B). In some other embodiments, the rinse manifold 290 is adjacent to the first side 206 (FIG. 2C). The HPC module 200 further includes a brush rinse 296 mounted to the basin 214. The brush rinse 296 is positioned towards the first end 202 of the HPC module 200 and adjacent to the pad conditioning station 280 for rinsing one or more components of the pad conditioning station 280.

In embodiments herein, the HPC module 200 includes a rotating chuck assembly having a carrier film disposed thereon and secured thereto. The chuck assembly uses vacuum pressure applied through a plurality of channels formed through the carrier film to hold the substrate in place during rotation. In some embodiments, the plurality of channels are formed in an array. The structural configuration of the channels used in typical carrier films can result in localized deformation of the substrate surface as well slippage of the substrate at higher torque. For example, areas of the substrate aligned with the array of vacuum channels may deform relative to adjacent areas of the substrate disposed over solid portions of the carrier film. Locally deformed areas of the substrate reduce buffing pad pressure applied thereto causing uneven substrate cleaning. Thus, embodiments described below reduce and/or substantially eliminate localized deformation of the carrier film.

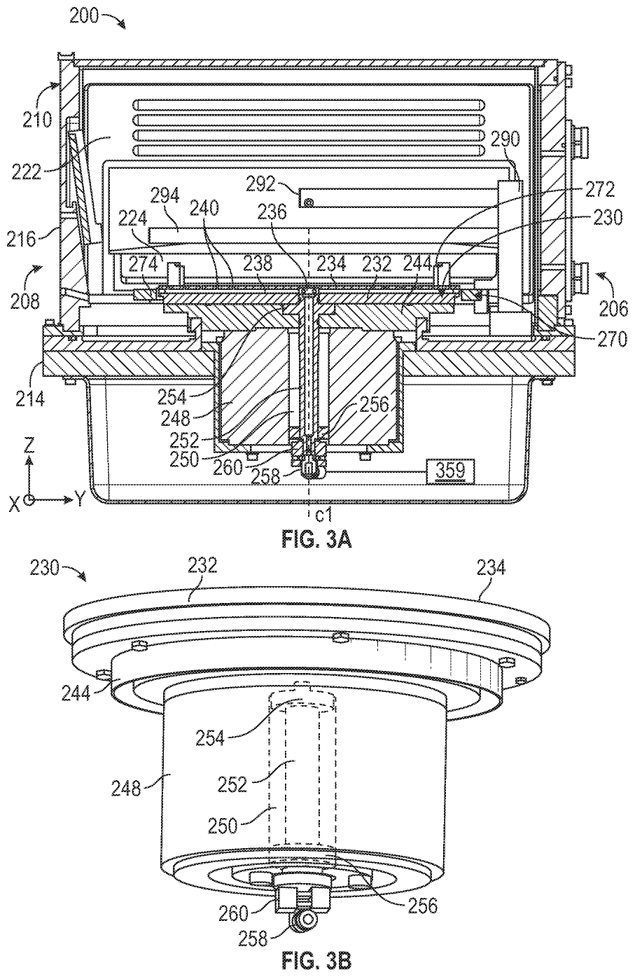

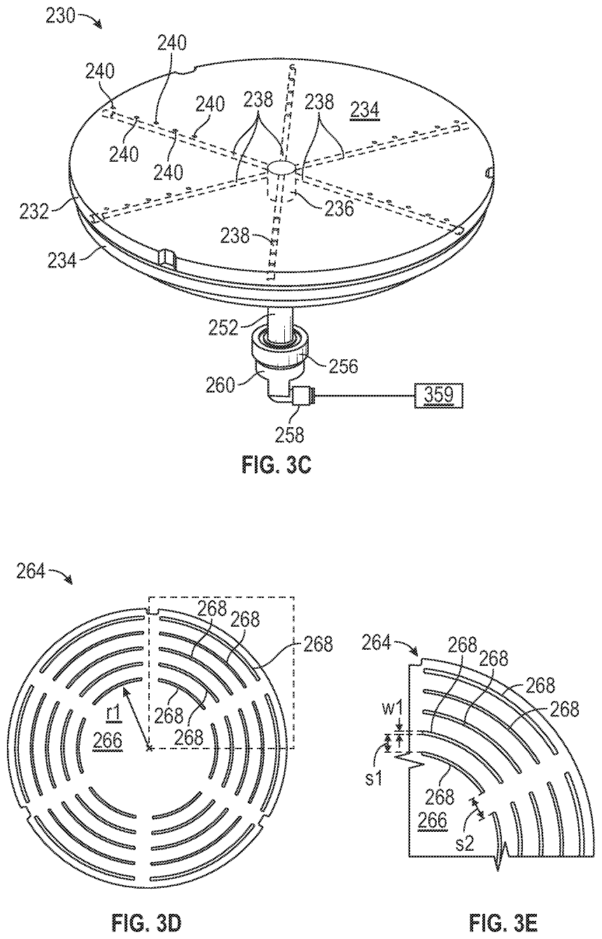

FIG. 3A is a side sectional view taken along section line 3A-3A of FIG. 2C. FIGS. 3B-3C are bottom and top isometric views, respectively, of an exemplary rotatable vacuum table 230 which may be used in the HPC module 200 of FIG. 3A. FIG. 3D is a plan view of an exemplary carrier film which may be used with the rotatable vacuum table 230 of FIGS. 3B-3C. FIG. 3E is an enlarged plan view of a portion of FIG. 3D.

The vacuum table 230 includes a chuck plate 232 having a top surface 234. The top surface 234 of the chuck plate 232 is substantially orthogonal to a direction of gravity. The chuck plate 232 is a cylindrical plate having a longitudinal axis c1 aligned in the direction of gravity. The chuck plate 232 includes a central bore 236 connecting a plurality of radial channels 238 that are, for example, formed in a radial array. Here, the chuck plate 232 has six equally circumferentially spaced channels 238. In some other embodiments, the chuck plate 232 includes from 3 to 12 channels, such as from 5 to 10 channels, such as from 6 to 8 channels. Each of the channels in the array of radial channels 238 extend from the central bore 236 to a plurality of ports 240 formed in the top surface 234. Here, each of the array of radial channels 238 includes five ports 240. In some other embodiments, each radial channel 238 includes from 3 to 7 ports, such as from 4 to 6 ports. Here, the plurality of ports 240 are equally spaced apart from one another in the radial direction along one of the array of channels 238. In some other embodiments, the plurality of ports 240 are non-uniformly spaced. The central bore 236, the array of radial channels 238, and the plurality of ports 240 are configured to provide pressure and fluid communication from a vacuum source 359 to the top surface 234 of the chuck plate 232 for vacuum chucking a substrate 120 thereon. In some embodiments, vacuum pressure is from about −8 psi to about −4.5 psi relative to atmospheric pressure, such as from about −7 psi to about −5.5 psi relative to atmospheric pressure. Thus, application of a negative vacuum pressure through the plurality of ports 240 secures the substrate 120 against the top surface 234. To remove the substrate 120 from the chuck plate 232, the vacuum pressure is vented and an optional positive pressure nitrogen purge is applied.

A bottom side of the chuck plate 232 is coupled to a chuck adapter 244. The chuck adapter 244 is a cylindrical plate disposed between and coupling the chuck plate 232 to a chuck motor 248. The chuck motor 248 is configured to rotate the chuck plate 232 and the chuck adapter 244 about the longitudinal axis c1. A longitudinal motor bore 250 of the chuck motor 248 houses a rotatable manifold 252 having a flange 254 at a proximal end. The flange 254 is coupled to the chuck adapter 244 such that the rotatable manifold 252 is rotated by the rotation of the chuck adapter 244. The chuck plate 232, chuck adapter 244, and rotatable manifold 252 are removable from the motor bore 250 as a sub-assembly. In some embodiments, the chuck plate 232, chuck adapter 244, rotatable manifold 252, screws and alignment pins between the chuck plate 232 and chuck adapter 244, and screws between the flange 254 and the chuck adapter 244 are formed from a plastic or polymer, e.g., polyether ether ketone (PEEK). Substituting plastic components throughout the sub-assembly in place of metal components, e.g., stainless steel, reduces trace metal contamination of the substrate 120. A bearing 256 is disposed within the motor bore 250 at a distal end of the rotatable manifold 252 for centering the rotatable manifold 252 within the motor bore 250. The bearing 256 has an inside diameter for rotatably coupling an outside diameter of the rotatable manifold 252 to facilitate relative rotation between the rotatable manifold 252 and the motor bore 250. A rotary elbow 258 is coupled to the distal end of the rotatable manifold 252 by a jam nut 260. The rotary elbow 258 provides pressure and fluid communication between a stationary vacuum source 359 and the rotatable manifold 252.

Referring to FIG. 3D, a carrier film 264 is disposed on the top surface 234 of the chuck plate 232. In some embodiments, the carrier film 264 is secured to the top surface 234 using an adhesive. In some embodiments, the carrier film 264 is removably attached to the top surface 234 such that the carrier film 264 can be replaced. The carrier film 264 has a supporting surface 266 (e.g., a substrate receiving surface) facing away from the top surface 234 of the chuck plate 232. The supporting surface 266 is substantially orthogonal to the direction of gravity. In some embodiments, the carrier film 264 has a closed cell porous structure to communicate vacuum pressure therethrough and to form a seal between the chuck plate 232 and the substrate 120. In some embodiments, the carrier film 264 is formed from a polymer or plastic, e.g., polyurethane. Beneficially, the carrier film 264 improves contact area between the chuck plate 232 and the substrate 120, reduces trace metal contamination, reduces scratching and defect formation due to particles trapped between the chuck plate 232 and the substrate 120, and/or optimizes distribution of vacuum pressure applied to the substrate 120. The carrier film 264 includes a plurality of channels 268 formed in an array in the supporting surface 266. The array of channels 268 are openings in the carrier film 264 that are in registration with corresponding ones of the annular channels disposed there beneath.

Here, the array of channels 268 are annular channels which encircle the longitudinal axis c1. In some other embodiments, the array of channels 268 have a non-annular shape. Here, an innermost channel of the array of channels 268 is spaced from the longitudinal axis c1 through a center of the carrier film 264 in the radial direction by a distance r1. In some embodiments, the distance r1 is about 100 mm or greater, such as from about 100 mm to about 200 mm, such as about 150 mm. Here, the carrier film 264 includes five concentric channels 268 having equal spacing s1 between adjacent channels 268 in the radial direction. In some other embodiments, the carrier film 264 includes from 3 to 7 concentric channels, such as from 4 to 6 concentric channels. In some other embodiments, the array of channels 268 are non-uniformly spaced. In some embodiments, the spacing s1 between the channels 268 is about 50 mm or less, such as from about 20 mm to about 50 mm, such as from about 30 mm to about 40 mm. Here, each of the array of channels 268 includes 6 arc-shaped segments. In some other embodiments, the array of channels 268 include from 3 to 12 arc-shaped segments, such as from 5 to 10 arc-shaped segments, such as from 6 to 8 arc-shaped segments. In some embodiments, a circumferential spacing s2 between adjacent arc-shaped segments of the same channel 268 is about 50 mm or less, such as from about 20 mm to about 50 mm.

Beneficially, the array of channels 268 have a width w1 that prevents deformation of the substrate 120 when vacuum is applied. In some embodiments, the width w1 is about 10 mm or less, such as about 5 mm or less, such as about 2 mm or less, such as about 1 mm or less, alternatively from about 1 mm to about 2 mm, such as about 1.5 mm. In some embodiments, using narrower channels 268 enables higher vacuum pressure to be applied without causing deformation of the substrate 120. In some embodiments, a grip area provided by the array of channels 268 is about 5% or greater of a surface area of a to-be-processed substrate 120 disposed thereon, such as between about 5% and about 30%, such as between about 10% and about 30%, such as between about 15% and about 30%, such as between about 15% and 25%, such as about 20%. The grip area is defined as the effective area occupied by the array of channels 268 in the supporting surface 266 of the vacuum table 230. In some embodiments, the HPC module 200 uses higher torque compared to the vertical cleaning modules 112. To handle higher torque relative to other designs, the array of channels 268 described herein have increased vacuum grip to prevent slippage of the substrate 120 from the vacuum table 230 without causing deformation of the substrate 120 where the increased vacuum grip is provided by higher grip area, higher vacuum pressure, or both.

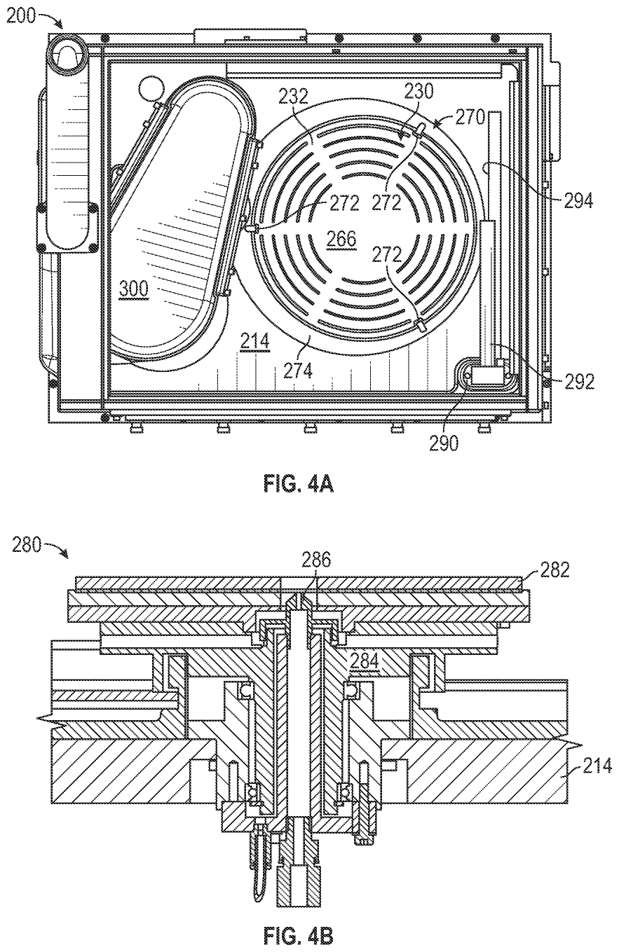

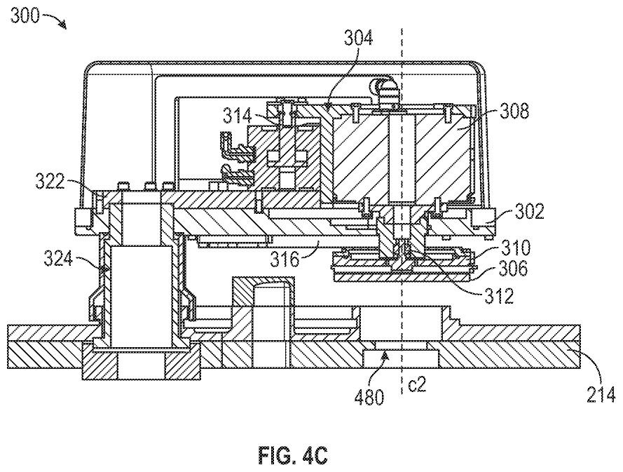

FIG. 4A is a plan view of the HPC module 200 of FIG. 2C. The annular substrate lift mechanism 270 is disposed radially outward of the vacuum table 230. The lift mechanism 270 includes a plurality of substrate contact points 272 disposed proximate to a circumferential edge of the vacuum table 230. Each of the substrate contact points 272 is an upward facing shoulder formed on a substrate hoop 274 surrounding the chuck plate 232. The lift mechanism 270 is configured so that one of the plurality of substrate contact points 272 contacts a substrate 120 before other ones of the plurality of substrate contact points 272 when lifting the substrate 120 from the supporting surface 266 of the vacuum table 230. The annular substrate lift mechanism 270 works in conjunction with the venting of vacuum pressure and optional nitrogen purge, described earlier, to remove the substrate 120 from the chuck plate 232. Beneficially, use of the substrate lift mechanism 270 enables faster dechucking of the substrate 120 relative to the venting and optional nitrogen purge alone.

FIG. 4B is a side sectional view of an exemplary pad conditioning station 280 which may be used in the HPC module 200 of FIG. 3A. The pad conditioning station 280 is disposed proximate to the rotatable vacuum table 230. The pad conditioning station 280 includes a conditioning brush 282 facing away from the basin 214. In some embodiments, the brush 282 includes a fibrous material. In some embodiments, the fibers are formed from nylon or another similar material. The brush 282 is coupled to a rotatable brush shaft 284. The brush shaft 284 extends through the basin 214 being fluidly coupled to a conditioning fluid source (not shown). The brush shaft 284 is configured to convey conditioning fluid, e.g., deionized water, to a spray nozzle 286 disposed proximate the brush 282. During operation of the pad conditioning station 280, the brush 282 is rotated by the brush shaft 284. During rotation, the conditioning fluid flows through the brush shaft 284 to the spray nozzle 286, thereby wetting the brush 282 and facilitating the conditioning process.

FIG. 4C is a side sectional view of an exemplary pad carrier positioning arm 300 which may be used in the HPC module 200 of FIG. 3A. The pad carrier positioning arm 300 is disposed proximate to the rotatable vacuum table 230 and the pad conditioning station 280. A distal end 302 of the pad carrier positioning arm 300 includes a vertically movable pad carrier assembly 304 for supporting a rotatable buffing pad 306 on a buffing pad support surface disposed at a lower end thereof. In some embodiments, the pad carrier assembly 304 is sized to support a buffing pad 306 having a diameter of about 67 mm, such as from about 67 mm to about 150 mm, such as about 67 mm, alternatively about 134 mm. In some embodiments, the pad carrier positioning arm 300 of the present disclosure supports a larger buffing pad 306 compared to conventional pre-clean modules, and the larger buffing pad improves performance and reduces buffing time. The pad carrier assembly 304 includes a head motor 308 for rotating the buffing pad 306 and buffing pad support surface about an axis c2 which is substantially aligned in the direction of gravity. The pad carrier assembly 304 includes a gimbal base 310 coupled to the head motor 308 by a spherical bearing 312 allowing a buffing pad support surface of the pad carrier assembly 304 to pivot relative to a plane orthogonal to the axis c2. For simplicity of disclosure, the pad conditioning station 280 is not shown in FIG. 4C for illustrative purposes, but would be disposed in a cavity 480.

Post CMP, the HPC module 200 is configured to clean away polishing slurry and debris before the substrate 120 dries. In some embodiments, the HPC module 200 replaces one or more cleaning steps performed by the plurality of polishing stations of the first portion 105 of processing system 100. The buffing pad 306 of the HPC module 200 has a smaller form factor than a polishing surface of the polishing stations because cleaning can be performed locally as opposed to removing material by CMP which is performed globally across the entire surface of the substrate 120. In other words, the buffing pad 306 is smaller in diameter than the substrate 120, sized only to perform localized buffing, and not designed to cover the entire surface of the substrate 120 at one time.

The pad carrier positioning arm 300 includes a linear actuator 314, e.g., a pneumatic cylinder, coupled between the pad carrier assembly 304 and a proximal end 322 of the pad carrier positioning arm 300. The linear actuator 314 is configured to raise and lower the pad carrier assembly 304 along the axis c2 for positioning the buffing pad 306 relative to a substrate 120 disposed on the rotatable vacuum table 230 or relative to the brush 282 of the pad conditioning station 280 in order to apply an operative downforce of the buffing pad 306 thereon. In some embodiments, a pressure applied between the buffing pad 306 and the surface of the substrate 120 is about 0.5 psi or more, such as from about 0.5 psi to about 4 psi, such as about 3 psi, alternatively about 4 psi. In some embodiments, a downforce thrust load applied by the buffing pad 306 against the substrate 120 is proportional to the pressure. In some embodiments, the thrust load is from about 0.5 lbf to about 100 lbf, such as from about 10 lbf to about 65 lbf. An underside of the pad carrier positioning arm 300 includes a chemistry manifold 316 having multiple spray nozzles to distribute chemistry, e.g., process fluids, onto the surface of the substrate 120.

The proximal end 322 of the pad carrier positioning arm 300 is coupled to an actuator 324, e.g., a motor, configured to swing the pad carrier assembly 304 between the first position over the rotatable vacuum table 230 and the second position over the pad conditioning station 280. The pad carrier positioning arm 300 is configured to swing the pad carrier assembly 304 through the service access panel opening 228 to facilitate maintenance access thereto.

In some embodiments, downforce of the pad carrier assembly 304, torque of the buffing pad 306, torque of the substrate 120, and retention force and grip force of the vacuum table 230 through the carrier film 264 are adjusted and controlled to optimize performance. In some embodiments, torque of the buffing pad 306 is about 2 Nm or greater, such as from about 2 Nm to about 6 Nm, such as from about 3 Nm to about 5 Nm. In some embodiments, torque of the substrate 120 is about 10 Nm or greater, such as from about 10 Nm to about 30 Nm, such as from about 15 Nm to about 25 Nm. In some embodiments, retention force on the wet substrate 120 is about 25 lbf or greater, such as about 30 lbf or greater, such as from about 30 lbf to about 40 lbf, such as about 30 lbf. In some embodiments, edge lift grip force on the wet substrate is about 2 lbf or greater, such as from about 2 lbf to about 3 lbf, such as from about 2 lbf to about 2.4 lbf.

While the foregoing is directed to embodiments of the present disclosure, other and further embodiments of the disclosure may be devised without departing from the basic scope thereof, and the scope thereof is determined by the claims that follow.

1. A substrate processing module, comprising:
a rotatable vacuum table disposed in a processing area of the substrate processing module, the rotatable vacuum table comprising a supporting surface that comprises an array of channels;
a pad conditioning station disposed proximate to the rotatable vacuum table;
a pad carrier positioning arm coupled to a pad carrier assembly; and
an actuator coupled to the pad carrier positioning arm and configured to position the pad carrier assembly over a first position disposed over the supporting surface of the rotatable vacuum table and over a second position disposed over the pad conditioning station.

2. The substrate processing module of claim 1, wherein a width of individual ones of the array of channels is about 10 mm or less.

3. The substrate processing module of claim 2, wherein a grip area provided to by the array of channels is between about 5% and about 30% of a surface area of a to-be-processed substrate disposed thereon, the grip area comprising an effective area occupied by the array of channels in the supporting surface of the vacuum table.

4. The substrate processing module of claim 1, wherein the pad carrier assembly is sized to support a buffing pad having a diameter of about 67 mm or more.

5. The substrate processing module of claim 1, wherein the supporting surface of the vacuum table is substantially orthogonal to a direction of gravity.

6. The substrate processing module of claim 1, further comprising an annular substrate lift mechanism disposed radially outward of the vacuum table.

7. The substrate processing module of claim 6, wherein the annular substrate lift mechanism comprises a plurality of substrate contact points disposed proximate to a circumferential edge of the vacuum table, and wherein the annular substrate lift mechanism is configured so that one of the plurality of substrate contact points contacts a substrate before other ones of the plurality of substrate contact points when lifting the substrate from the supporting surface of the vacuum table.

8. A method of processing a substrate, comprising:
positioning a substrate on a vacuum table of a substrate processing module, the vacuum table comprising a supporting surface that comprises an array of channels, wherein the supporting surface of the vacuum table is substantially orthogonal to a direction of gravity, and wherein a grip area provided by the array of channels is between about 5% and about 30% of a surface area of the substrate positioned thereon, the grip area comprising an effective area occupied by the array of channels in the supporting surface of the vacuum table; and
urging a buffing pad against a surface of the substrate while rotating the vacuum table there beneath, wherein the buffing pad has a diameter of about 67 mm or more and a pressure applied between the buffing pad and the surface of the substrate is about 3 psi or more.

9. The method of claim 8, further comprising a vacuum table film having the array of channels formed therethrough, the vacuum table film secured to a chuck plate of the vacuum table using an adhesive, the chuck plate having a plurality of openings disposed in a top surface thereof, wherein the array of channels in the vacuum table film are in registration with corresponding ones of the openings disposed there beneath.

10. The method of claim 8, wherein the vacuum table is disposed in a processing area of the substrate processing module, the substrate processing module comprising:
a chamber comprising a basin and a lid which collectively define the processing area;
the vacuum table disposed in the processing area;
a pad conditioning station disposed proximate to the vacuum table;
a pad carrier positioning arm coupled to a pad carrier; and
an actuator coupled to the pad carrier positioning arm and configured to position a pad carrier assembly over a first position disposed over the supporting surface of the vacuum table and over a second position disposed over the pad conditioning station.

11. A modular substrate processing system, comprising:
a substrate processing module, comprising:
a chamber comprising a basin and a lid, the lid comprising a plurality of side panels which, with the basin, collectively define a processing area;
a rotatable vacuum table disposed in the processing area;
a first substrate handler access door disposed in a first side panel of the plurality of side panels, wherein the first substrate handler access door is used for positioning a substrate on the rotatable vacuum table with a first substrate handler;
a second substrate handler access door disposed in a second side panel of the plurality of side panels, wherein the second substrate handler access door is used for removing the substrate from the rotatable vacuum table with a second substrate handler;
a pad conditioning station disposed proximate to the rotatable vacuum table; and
a pad carrier positioning arm coupled to a pad carrier assembly; and
an actuator coupled to the pad carrier positioning arm and configured to position the pad carrier assembly over a first position disposed over the rotatable vacuum table and over a second position disposed over the pad conditioning station.

12. The modular substrate processing system of claim 11, wherein a third side panel of the plurality of side panels features a service opening and the pad carrier positioning arm is configured to position the pad carrier assembly through the service opening to facilitate maintenance access thereto.

13. The modular substrate processing system of claim 11, further comprising:
a first substrate processing region comprising a plurality of polishing stations; and
a second substrate processing region comprising the substrate processing module and the first substrate handler, wherein the first substrate handler is positioned to transfer substrates from the first substrate processing region to the substrate processing module.

14. The modular substrate processing system of claim 13, wherein the second substrate processing region further comprises a substrate cleaning system and the substrate processing module is disposed above the substrate cleaning system.

15. The modular substrate processing system of claim 14, wherein the second substrate handler is positioned to transfer a substrate from the substrate processing module to a cleaning station of the substrate cleaning system disposed there beneath.

16. The modular substrate processing system of claim 11, wherein the substrate processing module further comprises an annular substrate lift mechanism surrounding the vacuum table.

17. The modular substrate processing system of claim 16, wherein the annular substrate lift mechanism comprises a plurality of substrate contact points disposed proximate to a circumferential edge of the vacuum table, and wherein the annular substrate lift mechanism is configured so that one of the plurality of substrate contact points contacts a substrate before other ones of the plurality of substrate contact points when lifting the substrate from a supporting surface of the vacuum table.

18. The modular substrate processing system of claim 11, wherein the vacuum table comprises an array of channels defined in a supporting surface thereof, wherein a width of individual ones of the array of channels is about 10 mm or less.

19. The modular substrate processing system of claim 18, wherein a grip area provided to by the array of channels is between about 5% and about 30% of a surface area of a to-be-processed substrate disposed thereon, the grip area comprising an effective area occupied by the array of channels in the supporting surface of the vacuum table.

20. The modular substrate processing system of claim 19, wherein the pad carrier assembly is sized to support a buffing pad having a diameter of about 67 mm or more.
